(19) United States
(12) Patent Application Publication
(10) Pub. No.: US 2010/0001401 A1
(43) Pub. Date: Jan. 7, 2010

(54) SEMICONDUCTOR DEVICE INCLUDING INTERCONNECT LAYER MADE OF COPPER

(76) Inventor: Kenji SAWAMURA, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/560,498

(22) Filed: Sep. 16, 2009

Related U.S. Application Data
(63) Continuation of application No. 11/749,921, filed on May 17, 2007.

(30) Foreign Application Priority Data
May 18, 2006 (JP) 2006-139271

(51) Int. Cl. H01L 23/52; H01L 23/535

(52) U.S. Cl. 257/751; 257/762; 257/E23.168; 257/E23.141

(57) ABSTRACT

A semiconductor device includes an interlayer insulating film, a barrier metal layer, a conductive layer and a first insulating film. The barrier metal layer is formed on a bottom surface and a side face of a trench made in the interlayer insulating film. The conductive layer is formed on the barrier metal layer. The conductive layer has its upper surface lower than an upper surface of an opening of the trench and buries a part of the trench. The first insulating film is formed on the conductive layer and is formed on the barrier metal layer on a side face of the opening of the trench. The first insulating film is made of a material having a dielectric constant higher than that of the interlayer insulating film.

### CROSS-REFERENCE TO RELATED APPLICATIONS

This application is a continuation of and claims the benefit of priority under 35 U.S.C. §120 from U.S. Ser. No. 11/749,921 filed May 17, 2007, and claims the benefit of priority under 35 U.S.C. §119 from Japanese Patent Application No. 2006-139271 filed May 18, 2006, the entire contents of each of which are incorporated herein by reference.

### BACKGROUND OF THE INVENTION

1. Field of the Invention

The present invention relates to a semiconductor device, and for example, to a structure of a metal interconnect layer made of copper.

2. Description of the Related Art

Conventionally, copper is widely used as an interconnect material of a semiconductor device. Additionally, for example, Jpn. Pat. Appln. KOKAI Publication Nos. 2000-323479 and 10-189590 propose a configuration in which a barrier metal layer, etc., is formed around copper to prevent the copper from diffusing into a surrounding interlayer insulating film.

However, the copper diffusion preventing effect is not sufficiently obtained in the conventional configuration. For this reason, when a large potential difference is applied between the adjacent interconnect layers, the copper diffuses into the interlayer insulating film by electric field stress, which sometimes results in a problem that a short circuit occurs between interconnects.

### BRIEF SUMMARY OF THE INVENTION

A semiconductor device according to an aspect of the present invention includes:

an interlayer insulating film;

a barrier metal layer formed on a bottom surface and a side face of a trench made in the interlayer insulating film;

a conductive layer formed on the barrier metal layer, the conductive layer having its upper surface lower than an upper surface of an opening of the trench and burying a part of the trench; and

a first insulating film formed on the conductive layer and formed on the barrier metal layer on a side face of the opening of the trench, the first insulating film being made of a material having a dielectric constant higher than that of the interlayer insulating film.

### BRIEF DESCRIPTION OF THE SEVERAL VIEWS OF THE DRAWING

FIG. 1 is a plan view showing a semiconductor device according to a first embodiment of the invention;

FIG. 2 is a sectional view taken along the line 2-2 of FIG. 1;

FIG. 3 is a sectional view taken along the line 3-3 of FIG. 1;

FIGS. 4 to 11 are sectional views sequentially showing first to eighth processes of fabricating the semiconductor device according to the first embodiment of the invention;

FIG. 12 is a sectional view showing the semiconductor device according to the first embodiment of the invention, and also shows a diffusion path of a Cu atom;

FIG. 13 is a sectional view showing the semiconductor device according to the first embodiment of the invention, and also shows a state of an electric field between metal interconnect layers;

FIG. 14 is a plan view showing a semiconductor device according to a second embodiment of the invention;

FIG. 15 is a sectional view taken along the line 15-15 of FIG. 14;

FIG. 16 is a sectional view taken along the line 16-16 of FIG. 14;

FIGS. 17 to 19 are sectional views sequentially showing first to third processes of fabricating the semiconductor device according to the second embodiment of the invention;

FIG. 20 is a sectional view showing the semiconductor device according to the second embodiment of the invention, and also shows a diffusion path of a Cu atom;

FIG. 21 is a sectional view showing the semiconductor device according to the second embodiment of the invention, and also shows a state of an electric field between metal interconnect layers;

FIG. 22 is a sectional view showing a semiconductor device according to a third embodiment of the invention;

FIG. 23 is a sectional view showing the semiconductor device according to the third embodiment of the invention;

FIGS. 24 and 25 are sectional views sequentially showing first and second processes of fabricating the semiconductor device according to the third embodiment of the invention;

FIG. 26 is a sectional view showing a semiconductor device according to a fourth embodiment of the invention;

FIG. 27 is a sectional view showing the semiconductor device according to the fourth embodiment of the invention;

FIG. 28 is a partially sectional view sequentially showing a process of fabricating the semiconductor device according to the fourth embodiment of the invention;

FIG. 29 is a plan view showing a semiconductor device according to a modification of the second and third embodiments of the invention;

FIG. 30 is a block diagram showing a NAND-type flash memory including an interconnect layer according to the first to fourth embodiments of the invention;

FIG. 31 is a sectional view showing a memory cell array of FIG. 30; and

FIG. 32 is a sectional view showing a row decoder of FIG. 30.

### DETAILED DESCRIPTION OF THE INVENTION

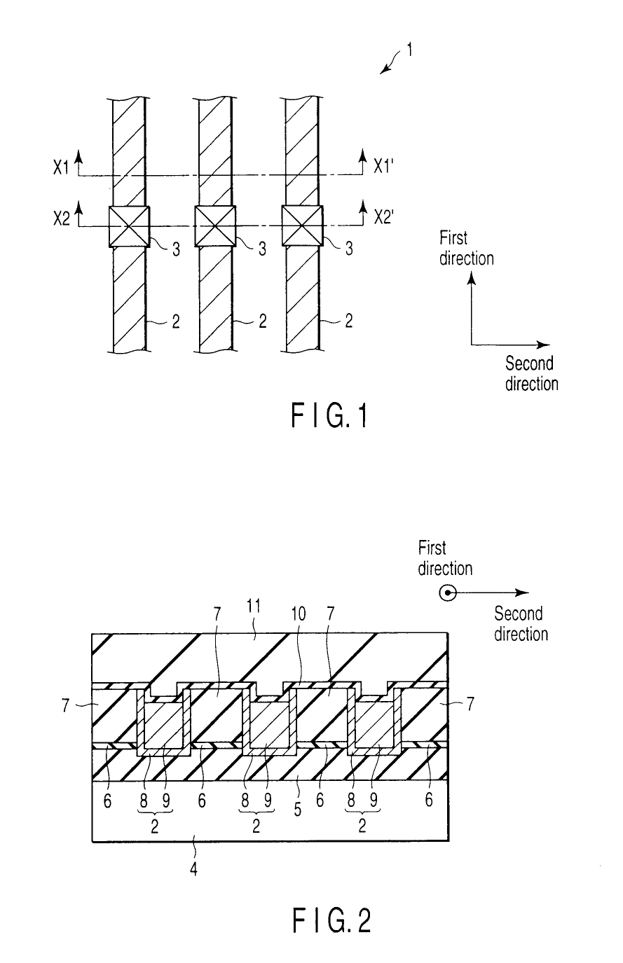

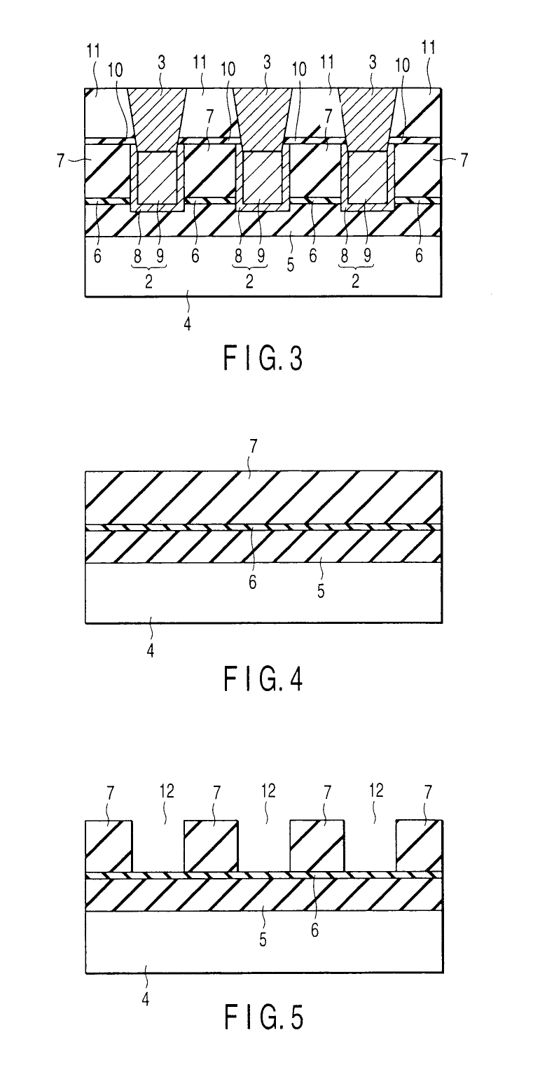

A semiconductor device according to a first embodiment of the invention will be described with reference to FIGS. 1 to 3. FIG. 1 is a plan view showing the semiconductor device of the first embodiment, and particularly FIG. 1 shows a metal interconnect layer and a contact plug provided on the metal interconnect layer. FIGS. 2 and 3 are sectional views taken along the lines 2-2 and 3-3 of FIG. 1, respectively.

As shown in FIG. 1, a semiconductor device 1 includes a plurality of metal interconnect layers 2.

Although only three metal interconnect layers are shown in FIG. 1, the embodiment is not limited thereto. Each metal interconnect layer 2 has a stripe shape along a first direction, and the metal interconnect layers 2 are adjacent to one another along a second direction orthogonal to the first direction. A contact plug 3 is formed on each metal interconnect layer 2. The contact plugs 3 are arranged in parallel to one another, namely the contact plugs 3 are arranged in line along the second direction.

A sectional structure of the semiconductor device 1 having the above configuration will be described with reference to FIGS. 2 and 3. As shown in FIGS. 2 and 3, an interlayer insulating film 5 is formed on a semiconductor substrate 4, an insulating film 6 is formed on the interlayer insulating film 5, and an interlayer insulating film 7 is formed on the insulating film 6. A U-shaped barrier metal layer 8 is formed in the interlayer insulating film 7. The U-shaped barrier metal layer 8 is formed in such a manner that it pierces through the insulating film 6 and a bottom thereof is located in the interlayer insulating film 5 while an upper end thereof reaches an upper surface of the interlayer insulating film 7. A conductive layer 9 is formed in the U-shaped barrier metal layer 8. The U-shaped barrier metal layer 8 is not completely filled with the conductive layer 9, and the upper end of the conductive layer 9 is located lower than the upper end of the barrier metal layer 8, i.e., the upper surface of the interlayer insulating film 7. An insulating film 10 is formed on the interlayer insulating film 7, on the conductive layer 9, and in a region of the barrier metal layer 8 where the barrier metal layer 8 is not filled with the conductive layer 9. An interlayer insulating film 11 is formed on the insulating film 10. In the above configuration, the barrier metal layer 8 and the conductive layer 9 function as the metal interconnect layer 2. In the region along the line 3-3 of FIG. 1, the contact plug 3 is formed in the interlayer insulating film 11 (FIG. 3). As shown in FIG. 3, the contact plug 3 pierces through the insulating film 10 from the upper surface of the interlayer insulating film 11 to reach the conductive layer 9.

A method of fabricating the semiconductor device 1 having the above configuration will be described below with reference to FIGS. 4 to 11. FIGS. 4 to 11 are sectional views sequentially showing processes of fabricating the semiconductor device 1 of the first embodiment.

As shown in FIG. 4, using SiO₂ as a material, the interlayer insulating film 5 (hereinafter sometimes referred to as SiO₂ film 5) is formed on the semiconductor substrate 4 in which semiconductor elements (not shown) are formed. Then, the insulating film 6 (hereinafter sometimes referred to as SiN film 6) is formed on the interlayer insulating film 5 using SiN as a material. Subsequently, the interlayer insulating film 7 (hereinafter sometimes referred to as SiO₂ film 7) is formed on the insulating film 6 using SiO₂ as a material.

As shown in FIG. 5, the interlayer insulating film 7 is etched to form a trench 12 using a photolithography technique and dry etching. At this point, the insulating film 6 functions as an etching stopper, and the insulating film 6 is exposed to a bottom surface of the trench 12. Accordingly, in addition to SiN, any material may be used as the material for the insulating film 6 as long as the material ensures sufficient etching selectivity for the interlayer insulating film 7 in the etching process.

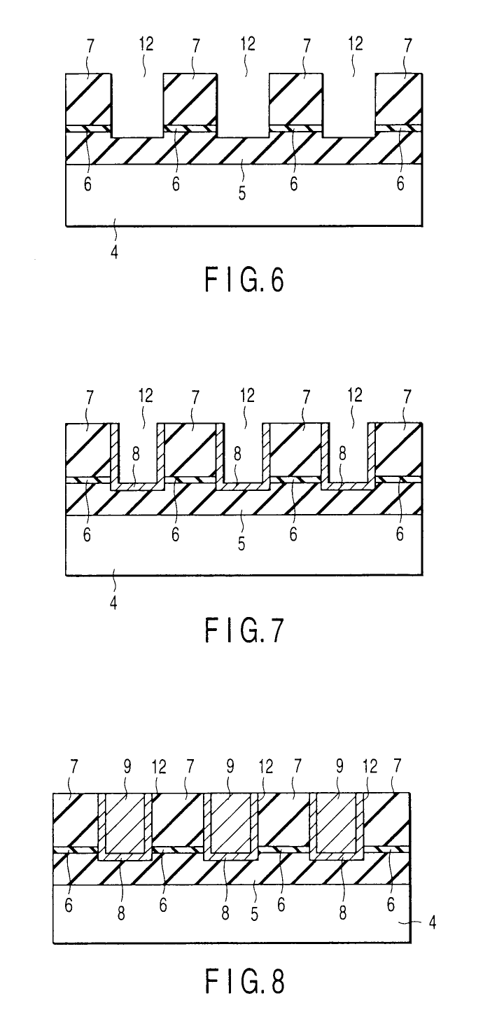

As shown in FIG. 6, the insulating film 6 existing in the bottom surface of the trench 12 is removed using dry etching or wet etching. At this point, not only the insulating film 6 but also a part of the interlayer insulating film 5 exposed to the bottom surface of the trench 12 may be etched. As a result, the bottom surface of the trench 12 is located in the interlayer insulating film 5.

As shown in FIG. 7, the thin barrier metal layer 8 is formed on the bottom surface and a side face of the trench 12. The barrier metal layer 8 is made of a metal such as Ta, TaN, Ti, and Mo, and has a single-layer structure or a laminated structure.

After a copper (Cu) seed layer is formed in the trench 12 and on the interlayer insulating film 7, Cu is buried in the trench 12 by a plating technique. Cu buried in the trench 12 is planarized by a chemical mechanical polishing (CMP) process using the interlayer insulating film 7 as a stopper. As a result, as shown in FIG. 8, the conductive layer 9 is obtained by Cu remaining in the trench 12. The barrier metal layer 8 is provided in order to prevent Cu in the conductive layer 9 from diffusing into the interlayer insulating films 5 and 7.

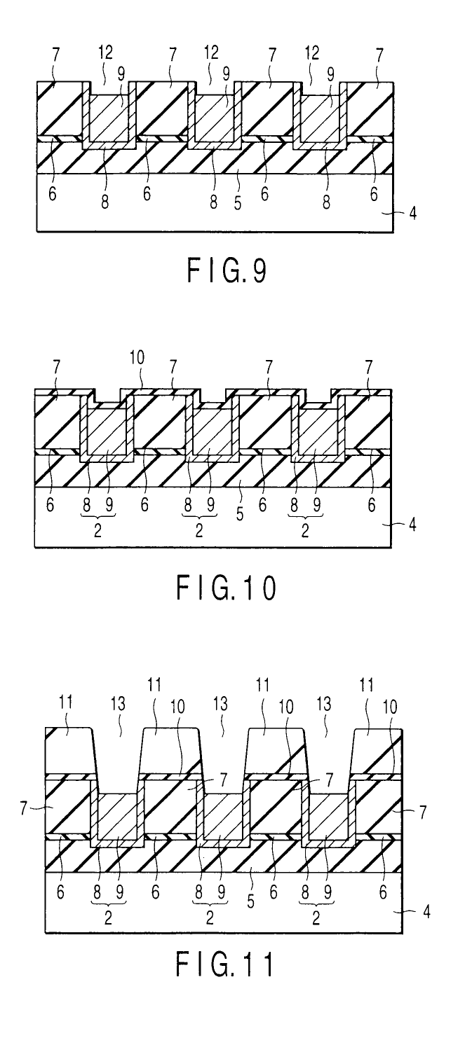

The CMP process is continuously performed under the condition that a polishing rate for Cu is higher than that for the interlayer insulating film 7. Consequently, as shown in FIG. 9, the upper surface of the conductive layer 9 is located lower than the upper surface of the interlayer insulating film 7, and an upper portion of the trench 12 is opened again. However, the barrier metal layer 8 remains up to the upper surface of the trench 12. As a result, the metal interconnect layer 2 including the barrier metal layer 8 and the conductive layer 9 is completed.

As shown in FIG. 10, the insulating film 10 (hereinafter sometimes referred to as SiN film 10) is formed on the conductive layer 9 in the opening of the trench 12, on the barrier metal layer 8, and on the interlayer insulating film 7 using, for example, SiN as a material.

Then, the interlayer insulating film 11 (hereinafter sometimes referred to as SiO₂ film 11) is formed on the insulating film 10 using, for example, SiO₂ as a material. As shown in FIG. 11, in the region where the contact plug 3 is formed, a contact hole 13 reaching the conductive layer 9 is made by the photolithography technique and anisotropic etching technique. Then, the contact plug 3 is formed to obtain the configuration shown in FIGS. 1 to 3 by filling the contact hole 13 with the conductive layer.

The semiconductor device and the fabricating method thereof obtain following effects 1 and 2.

(1) Cu is prevented from diffusing into the interlayer insulating film, so that reliability of the metal interconnect layer can be improved.

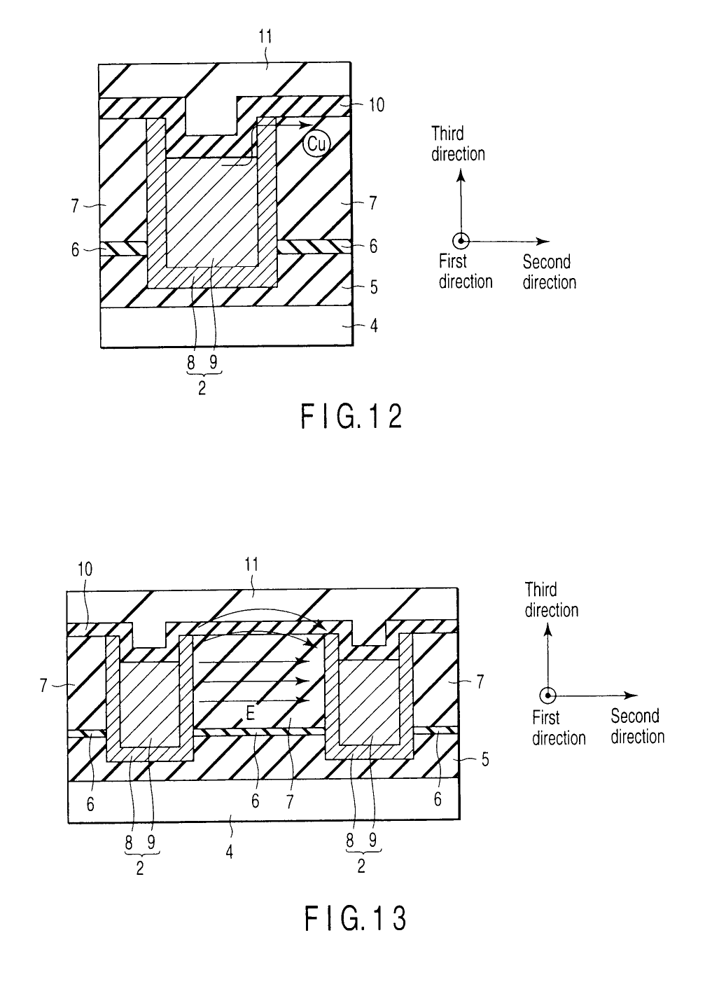

FIGS. 12 and 13 are enlarged views showing the metal interconnect layer 2 included in the semiconductor device of the first embodiment. FIG. 12 shows a Cu diffusion path, and FIG. 13 shows a state of an electric field generated between the interconnects.

As shown in FIG. 12, the conductive layer 9 made of Cu is completely surrounded by the barrier metal layer 8 and the SiN film 10. Specifically, the conductive layer 9 is formed in the U-shaped barrier metal layer 8. The upper surface of the conductive layer 9 is recessed from the upper-end position of the barrier metal layer 8, and is formed such that the U-shaped barrier metal layer 8 is not completely filled with the conductive layer 9. The SiN film 10 is formed on the conductive layer 9 and on the side face of the barrier metal layer 8 in the region where the conductive layer 9 is recessed.

A diffusion path through which a Cu atom in the conductive layer 9 diffuses into the interlayer insulating film 7 is shown by an arrow of FIG. 12. In order that Cu diffuses into the interlayer insulating film 7, it is necessary that Cu be moved along a connection portion between the barrier metal layer 8 and the SiN film 10. That is, it is necessary that Cu be moved along a third direction orthogonal to first and second directions, and also that Cu be moved along the second direction.

When a potential difference is generated between the adjacent metal interconnect layers 2, an electric field E does not exist substantially along the third direction, but the electric field E exists substantially along the second direction as shown in FIG. 13. Therefore, Cu cannot diffuse along the third direction. Cu is prevented from diffusing into the interlayer insulating film 7, so that the occurrence of a short circuit can be prevented between the metal interconnect layers 2 and the reliability of the metal interconnect layer 2 can be improved.

The same effect is obtained in the region where the contact plug 3 of FIG. 3 is formed. Even if the SiN film 10 on the conductive layer 9 is removed to form the contact plug 3, it is necessary that Cu be moved along the third direction to diffuse into the interlayer insulating film 7 because the upper portion of the conductive layer 9 is recessed from the upper end of the SiN film 10. Accordingly, Cu diffusion can be prevented even if the SiN film 10 is removed. As a result, as shown in FIG. 1, the contact plug 3 can be arranged along the second direction.

According to the fabricating method of the first embodiment, the CMP process is performed while the interlayer insulating film 7 is used as the stopper as shown in FIG. 8, and then, the CMP process is performed to the conductive layer 9 again as shown in FIG. 9. Therefore, even if the conductive layer 9 is partially left on the interlayer insulating film 7 by the first CMP process (FIG. 8), the conductive layer 9 can be removed by the second CMP process (FIG. 9). The conductive layer 9 remaining on the interlayer insulating film 7 tends to easily cause a short circuit of the metal interconnect layer 2. However, in the first embodiment, the residual conductive layer 9 on the interlayer insulating film 7 can effectively be prevented. This also enables the reliability of the metal interconnect layer 2 to be improved.

(2) Fabrication accuracy of the metal interconnect layer can be improved.

According to the configuration of the first embodiment, the SiN film 6 is provided as the etching stopper on the interlayer insulating film 5. In making the trench 12 for forming the metal interconnect layer 2, the etching of the interlayer insulating film 7 is tentatively stopped on the SiN film 6 (FIG. 5). Then, the SiN film 6 is peeled off from the bottom surface of the trench 12 to complete the trench 12 (FIG. 6). A depth of the trench 12 becomes the sum of a thickness of the interlayer insulating film 7, a thickness of the SiN film 6, and an over-etching depth (referred to as gouging amount) of the interlayer insulating film 5 upon peeling off the SiN film 6.

For all the trenches 12, the interlayer insulating films 7 are of the same thickness and the SiN films 6 are of the same thickness. Therefore, the gouging amount for each trench 12 becomes a factor of a fluctuation in depth of the trench 12. However, the gouging amount can be neglected because the gouging amount is overwhelmingly small compared with the thicknesses of the interlayer insulating film 7 and SiN film 6. As a result, the depths of the trenches 12 become substantially homogeneous, which allows the fabrication accuracy of the metal interconnect layer 2 to be improved. The interlayer insulating film 7 can be etched until reaching the SiN film 6, which clarifies an etching termination position of the interlayer insulating film 7. Accordingly, the depth control of the trench 12 can be facilitated to improve the fabrication accuracy of the metal interconnect layer 2.

Furthermore, the homogenization of the depth of the metal interconnect layer 2 leads to the improvement of performance of the semiconductor device 1. The fluctuation in depth of the metal interconnect layer 2 corresponds to a fluctuation in opposing area of a parasitic capacitor between the adjacent metal interconnect layers 2. The fluctuation in opposing area causes the fluctuation in capacitance of the parasitic capacitor. As a result, the interconnect capacitance between the metal interconnect layers 2 varies to worsen characteristics of the semiconductor device. However, in the configuration of the first embodiment, the depth of the metal interconnect layer 2 is substantially homogenized. Consequently, the fluctuation in capacitance of the interconnects can be suppressed to improve the characteristics of the semiconductor device 1.

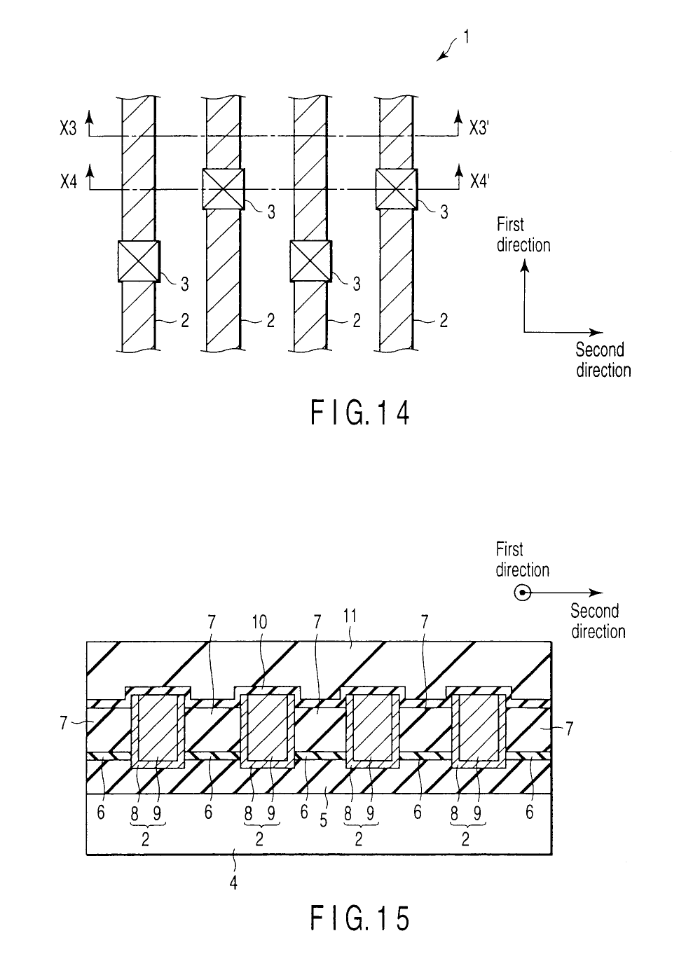

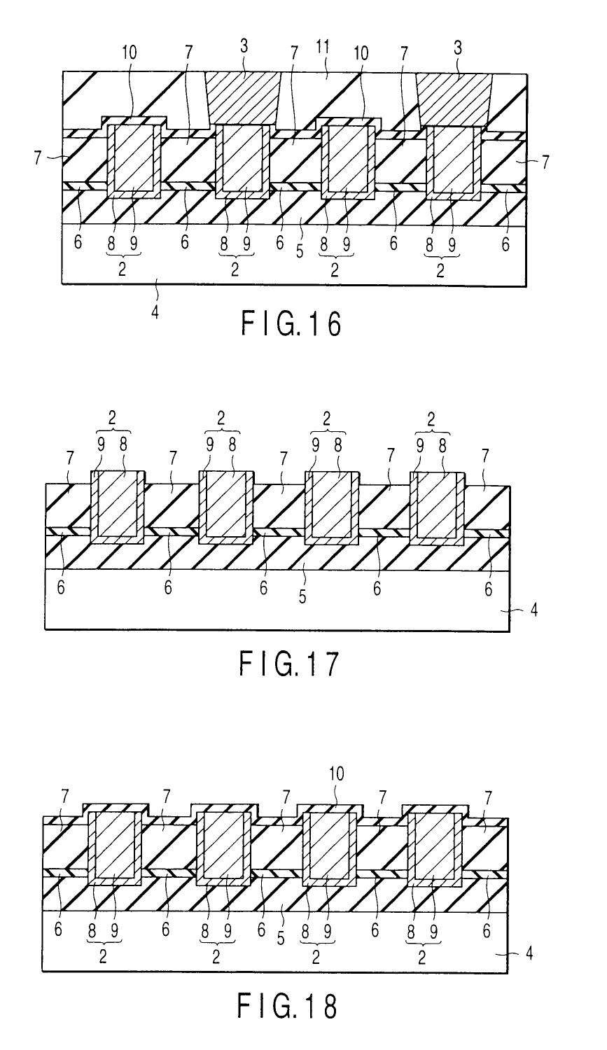

A semiconductor device according to a second embodiment of the invention will be described below. In the second embodiment, the positional relationship of the first embodiment between the upper surface of the conductive layer 9 and the upper surface of the interlayer insulating film 7 is changed. FIG. 14 is a plan view showing the semiconductor device of the second embodiment, and also shows a metal interconnect layer and a contact plug provided on the metal interconnect layer. FIGS. 15 and 16 are sectional views taken along the lines 15-15 and 16-16 of FIG. 14, respectively.

As shown in FIG. 14, a semiconductor device 1 includes a plurality of metal interconnect layers 2. Although only four metal interconnect layers are shown in FIG. 14, the embodiment is not limited thereto. Each metal interconnect layer 2 has a stripe shape along a first direction, and the metal interconnect layers 2 are adjacent to one another along a second direction orthogonal to the first direction. A contact plug 3 is formed on each metal interconnect layer 2. Unlike the first embodiment, the adjacent contact plugs 3 in the semiconductor device 1 of the second embodiment are arranged at different positions in the first direction. In other words, the contact plugs 3 are arranged in a zigzag manner.

A sectional structure of the semiconductor device 1 having the above configuration will be described with reference to FIGS. 15 and 16. As shown in FIGS. 15 and 16, an interlayer insulating film 5 is formed on a semiconductor substrate 4, an insulating film 6 is formed on the interlayer insulating film 5, and an interlayer insulating film 7 is formed on the insulating film 6. A U-shaped barrier metal layer 8 is formed in the interlayer insulating film 7. The U-shaped barrier metal layer 8 is formed in such a manner that it pierces through the insulating film 6 and a bottom thereof is located in the interlayer insulating film 5 while an upper end thereof is projected from an upper surface of the interlayer insulating film 7. The conductive layer 9 is formed in the U-shaped barrier metal layer 8. The U-shaped barrier metal layer 8 is completely filled with the conductive layer 9, and an upper end of the conductive layer 9 is equalized to an upper end of the barrier metal layer 8. Namely, an upper portion of the conductive layer 9 is also projected from the upper surface of the interlayer insulating film 7. An insulating film 10 is formed on the interlayer insulating film 7, on the barrier metal layer 8, and in a region of the conductive layer 9 where the conductive layer 9 is projected from the upper surface of the interlayer insulating film 7. As with the first embodiment, the barrier metal layer 8 and the conductive layer 9 function as the metal interconnect layer 2. In a region along the line 16-16 of FIG. 14, the contact plug 3 is formed in an interlayer insulating film 11 (FIG. 16). As shown in FIG. 16, the contact plug 3 pierces through the insulating film 10 from the upper surface of the interlayer insulating film 11 to reach the conductive layer 9.

A method of fabricating the semiconductor device 1 having the above configuration will be described with reference to FIGS. 17 to 19. FIGS. 17 to 19 are sectional views sequentially showing part of processes of fabricating the semiconductor device 1 of the second embodiment.

First, the structure shown in FIG. 8 is obtained by the process of the first embodiment. As shown in FIG. 17, using the dry etching or wet etching, the upper surface of the interlayer insulating film 7 located between the adjacent metal interconnect layers 2 is etched to the depth of at least 5 nm. As a result, as shown in FIG. 17, the upper portion of the metal interconnect layer 2 is projected from the interlayer insulating film 7.

As shown in FIG. 18, the insulating film 10 made of, for example, SiN is formed on the conductive layer 9 projected from the interlayer insulating film 7, on the barrier metal layer 8, and on the interlayer insulating film 7.

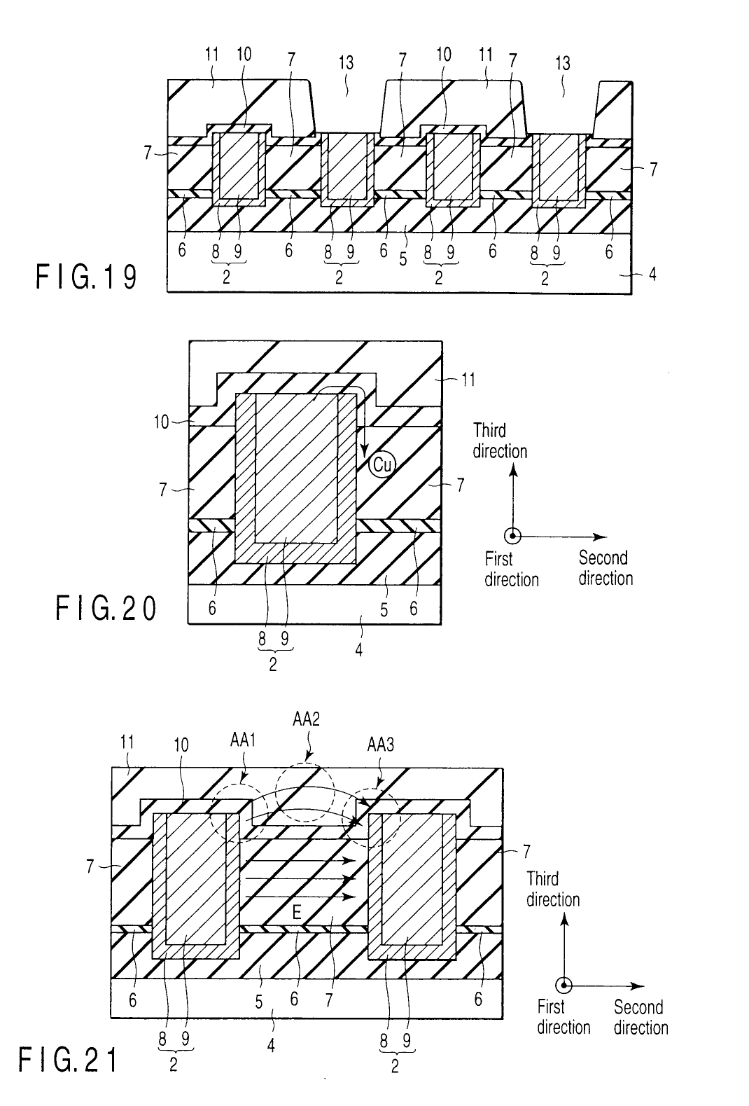

Then, the interlayer insulating film 11 made of, for example, SiO₂ is formed on the insulating film 10. As shown in FIG. 19, in a region where the contact plug 3 is formed, a contact hole 13 reaching the conductive layer 9 is made by the photolithography technique and anisotropic etching technique. Thereafter, the contact plug 3 is formed to obtain the configuration shown in FIGS. 14 to 16 by filling the contact hole 13 with the conductive layer.

In addition to the effect (2) of the first embodiment, the semiconductor device of the second embodiment and the fabricating method thereof obtain the following effects (3) and (4).

(3) Cu is prevented from diffusing into the interlayer insulating film, so that the reliability of the metal interconnect layer can be improved.

FIGS. 20 and 21 are enlarged views showing the metal interconnect layer 2 included in the semiconductor device of the second embodiment, FIG. 20 also shows a Cu diffusion path, and FIG. 21 shows a state of an electric field generated between metal interconnects.

As shown in FIG. 20, the conductive layer 9 made of Cu is completely surrounded by the barrier metal layer 8 and the SiN film 10. Specifically, the conductive layer 9 is formed in the U-shaped barrier metal layer 8. The upper surface of the interlayer insulating film 7 is recessed from the upper-end positions of the barrier metal layer 8 and conductive layer 9, and the barrier metal layer 8 and conductive layer 9 are projected from the upper surface of the interlayer insulating film 7. The SiN film 10 is formed on the side face of the barrier metal layer 8 projected from the interlayer insulating film 7, on the upper surface of the conductive layer 9, and on the interlayer insulating film 7.

A diffusion path through which a Cu atom in the conductive layer 9 diffuses into the interlayer insulating film 7 is shown by an arrow of FIG. 20. In order that Cu diffuses into the interlayer insulating film 7, it is necessary that Cu be moved along the connection portion between the barrier metal layer 8 and the SiN film 10. That is, it is necessary that Cu be moved along the second direction, and also that Cu be moved along a third direction orthogonal to the first and second directions.

When a potential difference is generated between the adjacent metal interconnect layers 2, an electric field E does not exist substantially along the third direction, but the electric field E exists substantially along the second direction as shown in FIG. 21. Therefore, Cu cannot diffuse along the third direction. Cu is prevented from diffusing into the interlayer insulating film 7. This makes it possible to prevent a short circuit from occurring between the metal interconnect layers 2 and to improve the reliability of the metal interconnect layer 2.

According to the configuration of the second embodiment, as shown in FIG. 16, the SiN film 10 on the upper surface of the metal interconnect layer 2 is removed from the region where the contact plug 3 is formed. Therefore, Cu diffuses easily into the conductive layer 9 in this region. However, the contact plugs 3 of the second embodiment are arranged in a zigzag manner as shown in FIG. 14. Therefore, an interval between the adjacent contact plugs 3 is larger than that of the arrangement of FIG. 1 in the first embodiment, allowing the configuration in which a short circuit hardly occurs between the contact plugs 3.

(4) The capacitance between interconnects of the semiconductor device can be decreased.

According to the configuration of the second embodiment, the upper surface of the interlayer insulating film 7 is lower than the upper surface of the metal interconnect layer 2 as shown in FIGS. 20 and 21. Accordingly, as shown in FIG. 21, the electric field E generated from a corner portion of the metal interconnect layer 2 reaches the adjacent metal interconnect layer 2 via the SiO₂ film 11 on the SiN film 10. Because SiO₂ has a dielectric constant larger than that of SiN, the electric field is weakened by passing through the SiO₂ film 11. More specifically, in FIG. 21, the electric field E generated in a region AA1 of the metal interconnect layer 2 passes through the SiN film 10, passes through a region AA2 of the SiO₂ film 10, and passes through the SiN film 10 again to reach a region AA3 of the adjacent metal interconnect layer 2. Consequently, the electric field is weakened in the region AA2 compared with the case in which the electric field does not pass through the SiO₂ film 10, and thereby concentration of the electric field is suppressed at the corner portion of the metal interconnect layer 2. As a result, the capacitance between the metal interconnect layers 2 can be decreased, which allows signal delay in the metal interconnect layer 2 to be suppressed.

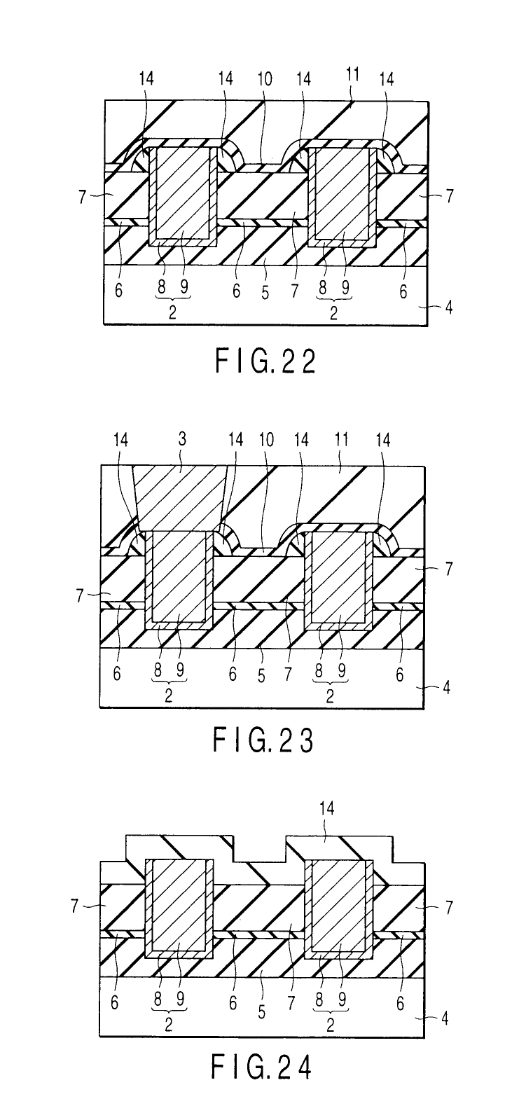

A semiconductor device according to a third embodiment of the invention will be described. The third embodiment differs from the second embodiment in that a sidewall insulating film is provided in a sidewall of the metal interconnect layer 2 projected from the interlayer insulating film 7. FIGS. 22 and 23 are sectional views showing the semiconductor device of the third embodiment. The planar configuration of the third embodiment is similar to that of FIG. 14 of the second embodiment. FIGS. 22 and 23 correspond to partially sectional views of regions taken along the lines 15-15 and 16-16 of FIG. 14, respectively.

As shown in FIGS. 22 and 23, the semiconductor device 1 of the third embodiment has the same configuration as that of FIGS. 15 and 16 of the second embodiment except that a sidewall insulating film 14 is provided on the sidewall of the barrier metal layer 8 and on the interlayer insulating film 7. The insulating film 10 is provided on the sidewall insulating film 14. That is, the sidewall insulating film 14 is provided between the barrier metal layer 8 and the insulating film 10.

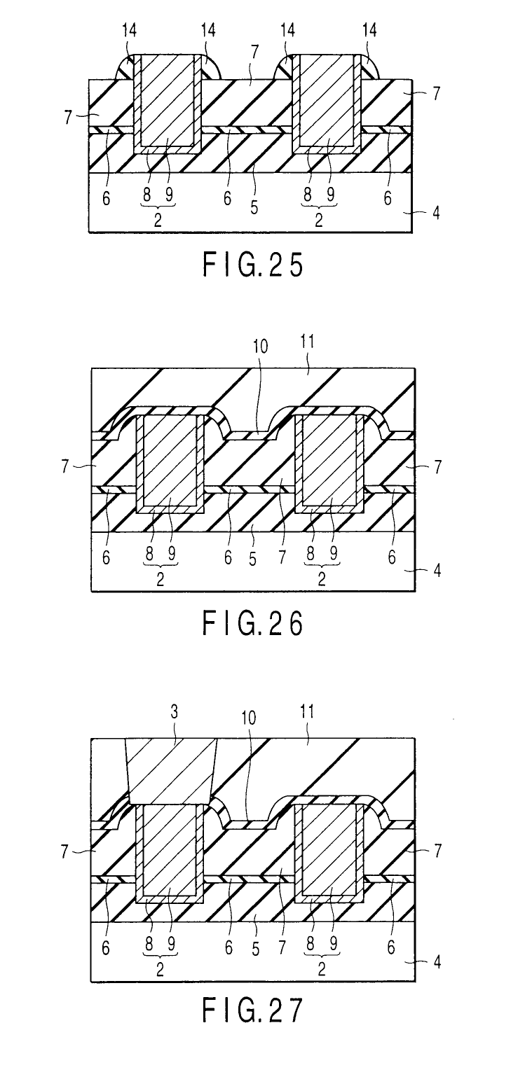

A method of fabricating the semiconductor device of the third embodiment will be described with reference to FIGS. 24 and 25. FIGS. 24 and 25 are sectional views sequentially showing part of processes of fabricating the semiconductor device of the third embodiment.

First, the configuration of FIG. 17 is obtained by the process of the second embodiment. As shown in FIG. 24, the insulating film 14 (hereinafter sometimes referred to as SiO₂ film 14) made of, for example, SiO₂ is formed on the interlayer insulating film 7 and on the metal interconnect layer 2 projected from the interlayer insulating film 7.

As shown in FIG. 25, the insulating film 14 is etched using the anisotropic etching technique, and thereby the insulating film 14 is allowed to remain only on the sidewall of the metal interconnect layer 2. Then, the configuration shown in FIGS. 22 and 23 is obtained by performing the processes on and after FIG. 18 of the second embodiment.

The semiconductor device 1 of the third embodiment obtains the following effect (5) in addition to the effect (2) of the first embodiment and the effects (3) and (4) of the second embodiment.

(5) Stress on the metal interconnect layer is reduced, so that the reliability of the metal interconnect layer can be improved.

According to the configuration of the third embodiment, the SiO₂ film 14 exists between the barrier metal layer 8 and the insulating film 10. Usually, SiN has a larger stress to be applied to the metal interconnect layer 2 than that of SiO₂. Accordingly, the SiO₂ film 14 is interposed to prevent the direct contact of the SiN film 10 with the sidewall portion of the metal interconnect layer 2, which makes it possible to reduce the stress applied to the metal interconnect layer 2. This results in improvement of the reliability of the metal interconnect layer 2.

In addition to SiO₂, any material may be used as the material for the sidewall insulating film 14 as long as the stress applied to the metal interconnect layer 2 is smaller than that of the insulating film 10.

Next, a semiconductor device according to a fourth embodiment of the invention will be described. In the fourth embodiment, the sidewall insulating film 14 of the third embodiment is formed by a part of the interlayer insulating film 7. FIGS. 26 and 27 are sectional views showing the semiconductor device of the fourth embodiment. The planar configuration of the fourth embodiment is similar to that of FIG. 14 of the second embodiment. FIGS. 26 and 27 correspond to the partially sectional views of regions taken along the lines 15-15 and 16-16 of FIG. 14, respectively.

As shown in FIGS. 26 and 27, the semiconductor device 1 of the fourth embodiment has the same configuration as that shown in FIGS. 15 and 16 of the second embodiment except that the interlayer insulating film 7 is provided on the sidewall of the barrier metal layer 8 and on the interlayer insulating film 7. The insulating film 10 is provided on the sidewall of the metal interconnect layer 2 with the interlayer insulating film 7 interposed therebetween. That is, the sidewall insulating film 14 is formed by a part of the interlayer insulating film 7 in the configuration shown in FIGS. 22 and 23 of the third embodiment.

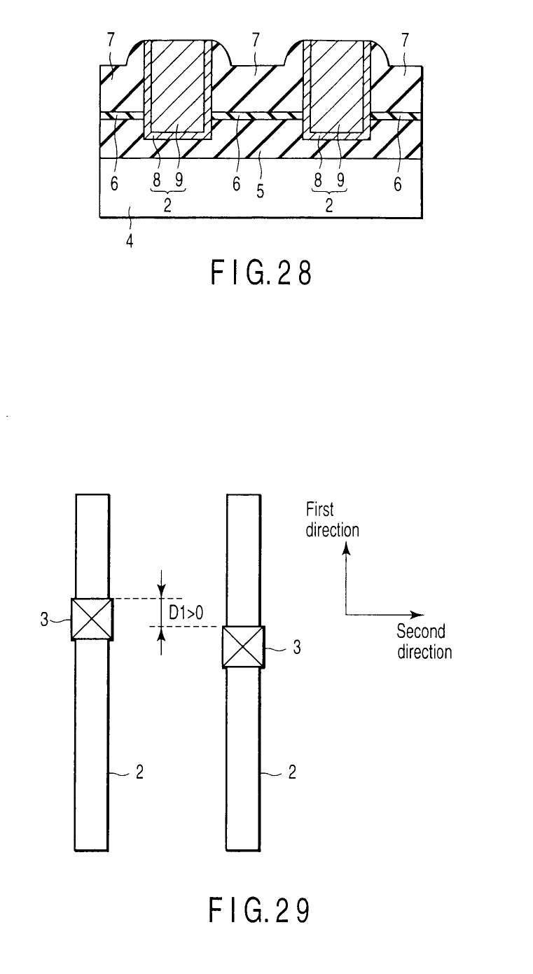

The method of fabricating the semiconductor device of the fourth embodiment will be described with reference to FIG. 28. FIG. 28 is a partially sectional view showing a part of the process of fabricating the semiconductor device of the fourth embodiment. First, the configuration of FIG. 8 is obtained by the process of the first embodiment. Then, the dry etching is employed to etch the upper surface of the interlayer insulating film 7 located between the adjacent metal interconnect layers 2 to the depth of at least 5 nm. At this point, unlike the process shown in FIG. 18 of the second embodiment, the etching is performed under the condition that a reaction product is deposited on the interlayer insulating film 7 during the etching. As a result, as shown in FIG. 28, a reaction product (SiO₂) is deposited in the sidewall portion of the metal interconnect layer 2, and the interlayer insulating film 7 is formed in a tapered shape. Then, the configuration shown in FIGS. 26 and 27 is obtained by performing the processes on and after FIG. 18 of the second embodiment.

The effect (2) described in the first embodiment, the effects (3) and (4) described in the second embodiment, and the effect (5) described in the third embodiment are obtained even in the configuration of the fourth embodiment. According to the fabricating method of the fourth embodiment, the fabricating process can be simplified to reduce production cost because the same structure is obtained by the number of processes smaller than that of the third embodiment.

Thus, according to the semiconductor devices of the first to fourth embodiments, in the metal interconnect layer 2, the conductive layer 9 including Cu is surrounded by the insulating film 10 and the barrier metal layer 8 which prevents the Cu diffusion. The connection portion, which becomes the Cu diffusion path, located between the barrier metal layer 8 and the insulating film 10, is formed such that the direction (third direction) of the connection portion differs from the direction (second direction) of the electric field between the adjacent metal interconnect layers 2. Therefore, the diffusion of Cu into the interlayer insulating film 7 is effectively prevented to improve the reliability of the semiconductor device 1.

In the first embodiment, the contact plugs 3 are arranged in parallel as shown in FIG. 1. However, in the first embodiment, the contact plugs 3 may be arranged in the zigzag manner like the second to fourth embodiments. Accordingly, a short circuit can effectively be prevented from occurring in the metal interconnect layer 2. The insulating film 6 which functions as the etching stopper is provided in the first to fourth embodiments. However, when the etching depth can be controlled upon making the trench 12, it is not always necessary that the insulating film 6 be provided.

The material of the insulating film 10 is not limited to SiN, but any material may be used as the insulating film 10 as long as it can prevent the diffusion of Cu in the conductive layer 9. Obviously, the material of the conductive layer 9 is not limited to Cu. In this case, the material which can prevent the diffusion of the atom in the conductive layer 9 may appropriately be used as the barrier metal layer 8 and the insulating film 10.

In the second embodiment, as shown in FIG. 14, the contact plugs 3 are arranged in the zigzag manner. At this point, it suffices that the adjacent contact plug 3 in the second direction be shifted along the first direction. That is, as shown in FIG. 29, it suffices that the shift amount of D1 along the first direction is greater than zero. As the shift amount D1 is increased, a short circuit can effectively be prevented. The shift amount D1 can appropriately be selected depending on the interval between the adjacent metal interconnect layers 2 and magnitude of voltage applied to the metal interconnect layer 2.

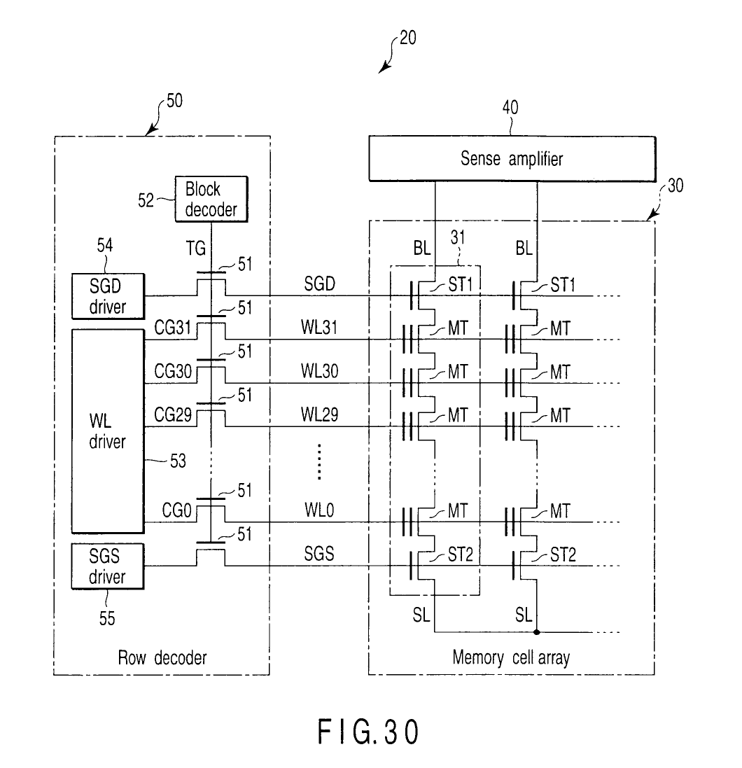

The semiconductor devices of the first to fourth embodiments can be applied to, for example, a NAND-type flash memory. The case in which the semiconductor device is applied to the NAND-type flash memory will be described below. FIG. 30 is a block diagram showing the NAND-type flash memory. As shown in FIG. 30, a NAND-type flash memory 20 includes a memory cell array 30, a sense amplifier 40, and a row decoder 50.

The memory cell array 30 includes a plurality of memory cell units 31 in which nonvolatile memory cells are connected in series. Each memory cell unit 31 includes 32 memory cell transistors MT and selection transistors ST1 and ST2. The memory cell transistor MT has a stacked gate structure. In the stacked gate structure, a charge accumulation layer (for example, floating gate) is formed on a semiconductor substrate with a gate insulating film interposed therebetween, and a control gate electrode is formed on the floating gate with an inter-gate insulating film interposed therebetween. The number of memory cell transistors MT is not limited to 32, but may be 8, 16, 64, 128, and 256. In the memory cell transistor MT, a source and a drain are shred by the adjacent memory cell transistors MT. A current path of the memory cell transistors MT is connected in series between the selection transistors ST1 and ST2. A drain region on one end side of the series memory cell transistors MT is connected to a source region of the selection transistor ST1, and a source region of the other end side of the series memory cell transistors MT is connected to a drain region of the selection transistor ST2.

The control gate electrodes of the memory cell transistors MT located in the same row are commonly connected to one of word lines WL0 to WL31, and gates of the selection transistors ST1 and ST2 of the memory cells located in the same row are commonly connected to select gate lines SGD and SGS, respectively. For the purpose of simple explanation, hereinafter sometimes the word lines WL0 to WL31 are simply referred to as word line WL. In the memory cell array 30, the drains of the selection transistors ST1 located in the same column are commonly connected to one of bit lines BL. The sources of the selection transistors ST2 are commonly connected to a source line SL. Both the selection transistors ST1 and ST2 are always not required, but any one of the selection transistors ST1 and ST2 may be provided as long as the memory cell unit 31 can be selected.

FIG. 30 shows only one-row memory cell unit 31. However, the memory cell units 31 may be provided in plural rows in the memory cell array 30. In such cases, the memory cell units 31 located in the same column are connected to the same bit line BL. Data is collectively written in the plural memory cell transistors MT connected to the same word line WL, and this unit is called page. The data is collectively erased in the plural memory cell units located in the same row, and this unit is called memory block.

The sense amplifier 40 senses and amplifies the data read to the bit line BL from the memory cell transistor MT.

The row decoder 50 selects a row direction of the memory cell array 30, i.e., a word line. As shown in FIG. 30, the row decoder 50 includes a transfer gate transistor 51, a block decoder 52, a word line driver 53, and select gate line drivers 54 and 55.

The transfer gate transistor 51 is provided in each word line WL and each of the select gate lines SGD and SGS, and one end of the current path is connected to the corresponding word line WL and select gate lines SGD and SGS. The other end of the current path of the transfer gate transistor 51 in which one end of the current path is connected to the word line WL is connected to the word line driver 53 through control gate lines CG0 to CG31. Hereinafter, when the control gate lines CG0 to CG31 do not distinguish from one another, the control gate lines CG0 to CG31 are simply referred to as control gate line CG. The other ends of the current path of the transfer gate transistors 51 in which one end of each of the current paths is connected to the select gate lines SGD and SGS are connected to the select gate line drivers 54 and 55, respectively. The select gate lines SGD and SGS which are connected to the selection transistors ST1 and ST2 and the memory cell transistors MT in the same memory block and the gates of the transfer gate transistors 51 which is connected to the word line WL are connected to the same control line TG.

The block decoder 52 turns on the transfer gate transistor 51 by selecting the control line TG connected to the transfer gate transistor 51 corresponding to the memory cell unit 31 including the selection memory cell.

The word line driver 53 selects one of the word lines WL according to an address given from the outside. The word line driver 53 applies a voltage to the selected word line WL through the control gate line CG and the current path of the transfer gate transistor 51. For example, upon writing the data, a positive voltage is applied to the selected word line WL. Upon reading the data, a voltage of zero is applied to the selected word line WL, and a positive voltage is applied to a non-selected word line. Upon erasing the data, the voltage of zero is applied to all the word lines WL.

The select gate line drivers 54 and 55 apply the voltage to the select gate lines SGD and SGS through the current paths of the transfer gate transistors 51 according to the address given from the outside, respectively.

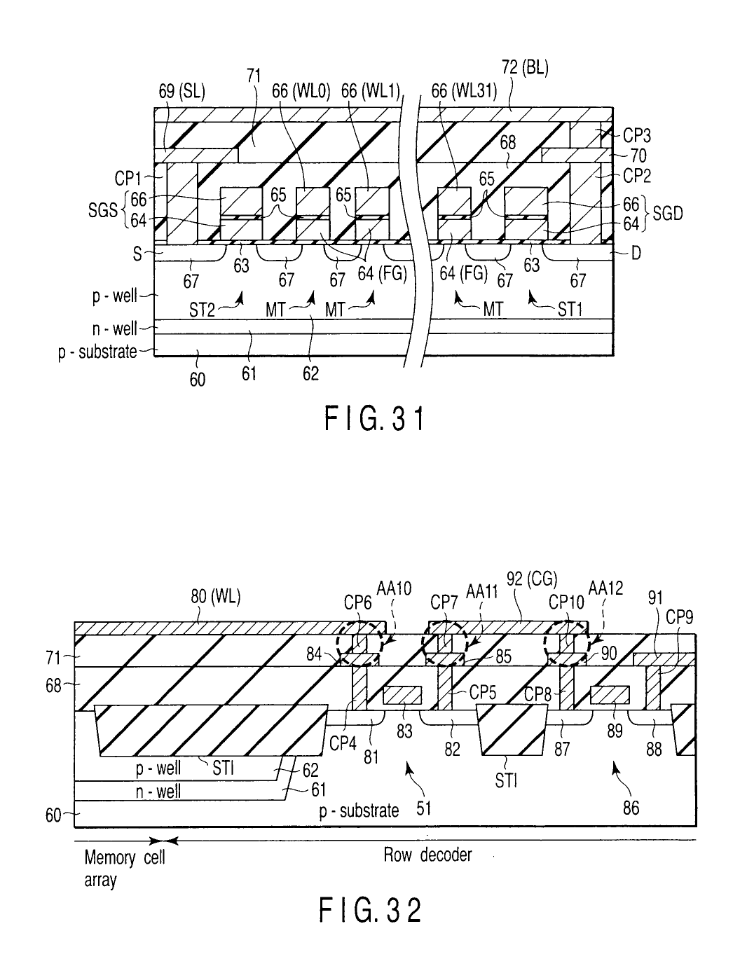

The sectional configuration of the memory cell unit 31 will be described with reference to FIG. 31. FIG. 31 is a sectional view taken along the bit line direction (first direction) of the memory cell array 31.

As shown in FIG. 31, an n-type well region 61 is formed in a surface region of a p-type semiconductor substrate 60, and a p-type well region 62 is formed in a surface region of an n-type well region 61. A gate insulating film 63 is formed on the p-type well region 62, the gate electrodes of the memory cell transistor MT and selection transistors ST1 and ST2 are formed on the gate insulating film 63. The gate electrodes of the memory cell transistor MT and selection transistors ST1 and ST2 each include a polycrystalline silicon layer 64, an inter-gate insulating film 65, and a polycrystalline silicon layer 66. The polycrystalline silicon layer 64 is formed on the gate insulating film 63, the inter-gate insulating film 65 is formed on the polycrystalline silicon layer 64, and the polycrystalline silicon layer 66 is formed on the inter-gate insulating film 65. For example, the inter-gate insulating film 65 is formed by a silicon oxide film, an ON film, an NO film, an ONO film having a laminated structure including a silicon oxide film and a silicon nitride film, a laminated structure including the NO film and the ONO film, or a laminated structure including the TiO₂, HfO₂, Al₂O₃, HfAlOₓ, or HfAlSi film and the silicon oxide film or the silicon nitride film. The gate insulating film 63 functions as a tunnel insulating film.

In the memory cell transistor MT, the polycrystalline silicon layer 64 functions as a floating gate (FG). On the other hand, the polycrystalline silicon layers 66 are commonly connected to each other in the polycrystalline silicon layers 66 which are adjacent to each other in the direction orthogonal to the bit line, and the polycrystalline silicon layer 66 functions as the control gate electrode (word line WL). In the selection transistors ST1 and ST2, the polycrystalline silicon layers 64 and 66 are commonly connected to each other in the polycrystalline silicon layers 64 and 66 which are adjacent to each other in the word-line direction. The polycrystalline silicon layers 64 and 66 function as the select gate lines SGS and SGD. Only the polycrystalline silicon layer 64 may function as the select gate line. In such cases, potentials at the polycrystalline silicon layers 66 in the selection transistors ST1 and ST2 are set in a floating state. An n+-type impurity diffusion layer 67 is formed in the surface of the semiconductor substrate 60 located between the gate electrodes. The impurity diffusion layer 67 is commonly used by the adjacent transistors, and functions as the source (S) or the drain (D). The region between the adjacent source and drain functions as a channel region which becomes an electron moving region. The MOS transistor functioning as the memory cell transistor MT and the selection transistors ST1 and ST2 are formed by the gate electrode, the impurity diffusion layer 67, and the channel region.

An interlayer insulating film 68 is formed on the semiconductor substrate 60 such that it covers the memory cell transistor MT and the selection transistors ST1 and ST2. A contact plug CP1 is formed in the interlayer insulating film 68, the contact plug CP1 reaching the impurity diffusion layer (source) 67 of the selection transistor ST2 on the source side. A metal interconnect layer 69 to be connected to the contact plug CP1 is formed on the interlayer insulating film 68. The metal interconnect layer 69 functions as a part of the source line SL. A contact plug CP2 is also formed in the interlayer insulating film 68, the contact plug CP2 reaching the impurity diffusion layer (source) 67 of the selection transistor ST1 on the drain side. A metal interconnect layer 70 connected to the contact plug CP2 is formed on the interlayer insulating film 68.

An interlayer insulating film 71 is formed on the interlayer insulating film 68 such that it covers the metal interconnect layers 69 and 70. A contact plug CP3 is formed in the interlayer insulating film 71, the contact plug CP3 reaching the metal interconnect layer 70. A metal interconnect layer 72 connected to the plural contact plugs CP3 is formed on the interlayer insulating film 71. The metal interconnect layer 72 functions as the bit line BL.

FIG. 32 is a sectional view, taken along the word line direction, showing the region from the boundary between the memory cell array 30 and the row decoder 50 to the inside of the row decoder 50. As shown in FIG. 32, a shallow trench isolation ST1 (element isolation region) is formed in the semiconductor substrate 60 at a boundary portion between the memory cell array 30 and the row decoder 50. A metal interconnect layer 80 is also formed on the interlayer insulating film 71, the metal interconnect layer 80 being connected to the word line WL in a region (not shown). The metal interconnect layer 80 is drawn from the inside of the memory cell array 30 to the inside of the row decoder 50.

In the row decoder 50, the transfer gate transistor 51 is formed on the semiconductor substrate 60. The transfer gate transistor 51 includes impurity diffusion layers 81 and 82 and a gate 83. The impurity diffusion layer 81 functions as one of the source and drain of the transfer gate transistor 51, and the impurity diffusion layer 82 functions as the other of the source and drain. The gate 83 is formed between the impurity diffusion layers 81 and 82 on the semiconductor substrate 60 while a gate insulating film is interposed between the gate 83 and the semiconductor substrate 60. The gate 83 functions as the control line TG of FIG. 30.

Contact plugs CP4 and CP5 to be connected to the impurity diffusion layer 81 and 82 are respectively formed in the interlayer insulating film 68. Metal interconnect layers 84 and 85 to be connected to the contact plug CP4 and CP5 are respectively formed on the interlayer insulating film 68. Contact plugs CP6 and CP7 to be connected to the impurity diffusion layer 84 and 85 are respectively formed in the interlayer insulating film 71.

A MOS transistor 86 in the word line driver 53 is formed on the semiconductor substrate 60 in the row decoder 50. The MOS transistor 86 includes impurity diffusion layers 87 and 88 and a gate 89. The impurity diffusion layer 87 functions as one of the source and drain of the MOS transistor 86, and the impurity diffusion layer 88 functions as the other of the source and drain. The gate 89 is formed between the impurity diffusion layers 87 and 88 on the semiconductor substrate 60 while the gate insulating film is interposed between the gate 89 and the semiconductor substrate 60.

Contact plugs CP8 and CP9 to be connected to the impurity diffusion layer 87 and 88 are respectively formed in the interlayer insulating film 68. Metal interconnect layers 90 and 91 to be connected to the contact plug CP8 and CP9 are respectively formed on the interlayer insulating film 68. A contact plug CP10 to be connected to the impurity diffusion layer 90 is formed in the interlayer insulating film 71. A metal interconnect layer 92 connected to the contact plug CP6 and CP7 is formed on the interlayer insulating film 71. The metal interconnect layer 92 functions as the control gate line CG of FIG. 30.

The configurations of the above embodiments are applied to regions AA10, AA11, and AA12 of FIG. 32. That is, the metal interconnect layers 84, 85, and 90 are formed so as to become the sectional structures shown in FIG. 2, 15, 22 or 26. In the case where the second to fourth embodiments are applied, the contact plugs CP6 (or CP7 or CP10) adjacent in the vertical direction on the paper plane of FIG. 32 are arranged in the zigzag manner as shown in FIG. 14.

In the NAND-type flash memory, a high voltage ranging from about 20 to about 25 V is applied to the word line upon writing the data. Therefore, a short circuit easily occurs in the metal interconnect layer of the word line driver 53 which applies the voltage to the word line. For this reason, it is preferable to apply the configurations of the first to fourth embodiments to the metal interconnect layer of the word line driver 53. The configurations of the first to fourth embodiments can be applied to not only the NAND-type flash memory but also various memory devices such as a NOR-type flash memory, and obviously the configurations of the first to fourth embodiments memory device can be applied to not only the memory devices but also various semiconductor devices.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
an interlayer insulating film;
a plurality of interconnect layers which are formed to be extended in a first direction in the interlayer insulating film and are adjacent to each other in a second direction orthogonal to the first direction, the interconnect layer including a conductive layer and a barrier metal layer, the conductive layer being formed in the interlayer insulating film and being partially projected from the interlayer insulating film, the barrier metal layer being formed on a bottom surface and a side face of the conductive layer;
a first insulating film formed on the interconnect layer, the first insulating film being formed on a region of the conductive layer projected from the interlayer insulating film and on the barrier metal layer on a side face in the projected region, and being made of a material having a dielectric constant higher than that of the interlayer insulating film; and
a plurality of first contact plugs which are in contact with the respective interconnect layers, the first contact plugs adjacent to each other in the second direction on the interconnect layer are shifted in the first direction.

2. The device according to claim 1, further comprising a second insulating film formed in the interlayer insulating film and made of a material which differs from the interlayer insulating film in an etching rate,
wherein the conductive layer is formed to pierce through the second insulating film in the interlayer insulating film.

3. The device according to claim 1, further comprising a sidewall insulating film formed on a side face of the barrier metal layer located on a side face of the projected region of the conductive layer, the sidewall insulating film being made of the same material as the interlayer insulating film,
wherein the first insulating film located on the side face of the projected region of the conductive layer is formed on the sidewall insulating film.

4. The device according to claim 3, wherein the sidewall insulating film is a part of the interlayer insulating film.

5. The device according to claim 1, wherein the interlayer insulating film is formed by a silicon oxide film, the conductive layer is made of copper, and the first insulating film is formed by a silicon nitride film.

6. The device according to claim 3, wherein the interlayer insulating film is formed by a silicon oxide film, and the second insulating film is formed by a silicon nitride film.

7. The device according to claim 1, further comprising
first and second selection transistors;
a plurality of memory cell transistors whose current paths are connected in series between a source of the first selection transistor and a drain of the second selection transistor, each of the memory cell transistors having a stacked gate including a charge accumulation layer and a control gate formed on the charge accumulation layer;
word lines each of which is connected to one of the control gates; and
a row decoder which selects the word lines to apply a voltage,
wherein the row decoder includes
transfer gate transistors each of which is provided in each of the word lines, the transfer gate transistors being covered with the interlayer insulating film;
second contact plugs each of which is in contact with one of impurity diffusion layers, each of the impurity diffusion layers being formed in the interlayer insulating film and functioning as a source or a drain of each of the transfer gate transistors; and
a word line driver which applies the voltage to the word lines through the current paths of the transfer gate transistors, the interconnect layers being connected to the respective second contact plugs, the first contact plugs being connected to the respective word lines.

8. A semiconductor device comprising:
an interlayer insulating film;
a conductive layer formed in the interlayer insulating film, the conductive layer being partially projected from the interlayer insulating film;
a barrier metal layer formed on a bottom surface and a side face of the conductive layer;
a first insulating film formed on a region of the conductive layer projected from the interlayer insulating film and on the barrier metal layer on a side face in the projected region, the first insulating film being made of a material having a dielectric constant higher than that of the interlayer insulating film; and
a second insulating film formed in the interlayer insulating film and made of a material which differs from the interlayer insulating film in an etching rate, the conductive layer being formed to pierce through the second insulating film in the interlayer insulating film.

9. The device according to claim 8, further comprising a sidewall insulating film formed on the barrier metal layer located on a side face of the projected region of the conductive layer, the sidewall insulating film being made of the same material as the interlayer insulating film,
wherein the first insulating film located in the side face of the projected region of the conductive layer is formed on a sidewall insulating film.

10. The device according to claim 9, wherein the sidewall insulating film is a part of the interlayer insulating film.

11. The device according to claim 8, wherein the interlayer insulating film is formed by a silicon oxide film, the conductive layer is made of copper, and the first insulating film is formed by a silicon nitride film.

12. The device according to claim 8, further comprising:
first and second selection transistors;
a plurality of memory cell transistors whose current paths are connected in series between a source of the first selection transistor and a drain of the second selection transistor, each of the memory cell transistors having a stacked gate including a charge accumulation layer and a control gate formed on the charge accumulation layer;
word lines each of which is connected to one of the control gates; and
a row decoder which selects the word lines to apply a voltage,
wherein the row decoder includes
transfer gate transistors each of which is provided in each of the word lines, the transfer gate transistor being covered with the interlayer insulating film;
first contact plugs each of which is in contact with one of impurity diffusion layers, each of the impurity diffusion layers being formed in the interlayer insulating film and functioning as a source or a drain of each of the transfer gate transistors;
metal interconnect layers each of which is in contact with each of the first contact plugs, the metal interconnect layers including the barrier metal layer and the conductive layer;
second contact plugs each of which is in contact with each of the metal interconnect layers, the second contact plugs electrically connecting each of the metal interconnect layers and each of the word lines; and
a word line driver which applies the voltage to the word lines through the current paths of the transfer gate transistors.
